(19) United States
(12) Patent Application Publication
(10) Pub. No.: US 2010/0079174 A1
(43) Pub. Date: Apr. 1, 2010

(54) FREQUENCY SYNTHESIZER AND METHOD FOR SYNTHESIZING FREQUENCY

(75) Inventors: Meng-Ting Tsai, Taichung City (TW); Ming-Bin Chen, Kaohsiung County (TW); Yu Lee, Pingtung County (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(73) Assignee: INDUSTRIAL TECHNOLOGY RESEARCH INSTITUTE, Hsinchu (TW)

(21) Appl. No.: 12/265,685

(22) Filed: Nov. 5, 2008

(30) Foreign Application Priority Data
Oct. 1, 2008 (TW) 97137753

(51) Int. Cl. H03B 21/00

(52) U.S. Cl. 327/105

(57) ABSTRACT

A frequency synthesizer includes a multi-signal comparing phase frequency detector/converter, a loop filter, a controllable oscillator, and a frequency divider. The multi-signal comparing phase frequency detector/converter simultaneously receives N input reference frequency signals and N feedback reference frequency signals. Frequencies of the input reference frequency signals are equivalent to one another while phases thereof are different from one another. Frequencies of the feedback reference frequency signals are equivalent to one another while phases thereof are different from one another. The multi-signal comparing phase frequency detector/converter compares the input reference frequency signals and corresponding feedback reference frequency signals, and then outputs a comparison control signal according to the comparison result. The frequency synthesizer of the present invention is adapted to depress a reference spur, thus achieving an ideal output frequency signal.

### CROSS-REFERENCE TO RELATED APPLICATION

This application claims the priority benefit of Taiwan application serial no. 97137753, filed on Oct. 1, 2008. The entirety of the above-mentioned patent application is hereby incorporated by reference herein and made a part of this specification.

### FIELD OF THE INVENTION

The present invention generally relates to a frequency synthesizer and a method for synthesizing frequency.

### BACKGROUND

Recently, the booming wireless technology has popularized wireless communication in our daily lives, e.g., mobile phones, wireless local area networks (WLANs), Bluetooth, ultra wide bands (UWBs), industrial scientific and medical (ISM), and worldwide interoperability for microwave access (WiMAX). Responsive to the demands for local oscillation signals and communication channel selection in a wireless communication system, a frequency synthesizer was proposed. When wireless communication is extensively applied, it requires the frequency synthesizer to produce high quality output signals. The local oscillation signals generated thereby should be clean, stable and programmable, so that the frequency synthesizer can be compatible with a wireless transceiver.

However, when used for such a wireless transceiver, in addition to phase noises, the frequency synthesizer is mainly affected by reference spurs, which often seriously destroys the performance of the wireless communication system.

### SUMMARY OF THE INVENTION

Accordingly, an exemplary embodiment consistent with the present invention, disclosed a frequency synthesizer, the frequency synthesizer comprising: a multi-signal comparing phase frequency detector/converter, a loop filter, a controllable oscillator, and a frequency divider. The multi-signal comparing phase frequency detector/converter is coupled to the loop filter. The loop filter is coupled to the controllable oscillator. The controllable oscillator is coupled to the frequency divider. The frequency divider is coupled to the multi-signal comparing phase frequency detector/converter. The multi-signal comparing phase frequency detector/converter is adapted for simultaneously receiving N input reference frequency signals and N feedback reference frequency signals. Frequencies of the input reference frequency signals are equivalent to one another while phases of the input reference frequency signals are different from one another, and frequencies of the feedback reference frequency signals are equivalent to one another while phases of the feedback reference frequency signals are different from one another. N is a positive integer greater than 1. Further, the multi-signal comparing phase frequency detector/converter compares each of the input reference frequency signals with a corresponding feedback reference frequency signal to obtain a comparison result, and outputs a comparison control signal according to the comparison result. The loop filter filters the comparison control signal to maintain the stability of the system, and outputs a frequency control signal. The controllable oscillator receives the frequency control signal, and outputs an output frequency signal and adjusts the frequency of the output frequency signal according to the received frequency control signal. The frequency divider receives the output frequency signal, and transforms the output frequency signal into the foregoing feedback reference frequency signals.

Also consistent with the invention, there is provided a frequency synthesizer, the frequency synthesizer comprising: a pseudo-random binary sequence (PRBS) generator, a multiplexer, a multi-signal comparing phase frequency detector/converter, a loop filter, a controllable oscillator, and a frequency divider. The multiplexer is coupled to the PRBS generator, the frequency divider and the multi-signal comparing phase frequency detector/converter. The multi-signal comparing phase frequency detector/converter is coupled to the loop filter. The loop filter is coupled to the controllable oscillator. The controllable oscillator is coupled to the frequency divider. The PRBS generator is adapted for generating random number selecting signals. The multiplexer receives 2N input reference frequency signals, 2N feedback reference frequency signals, and the random number selecting signals. Frequencies of the 2N input reference frequency signals are equivalent to one another while phases thereof are different from one another. Frequencies of the 2N feedback reference frequency signals are equivalent to one another while phases thereof are different from one another. N is a positive integer greater than 1. The multiplexer is adapted to sequentially select N from the 2N input reference frequency signals for outputting according to a sequence of the random number selecting signals, and sequentially select N from the 2N feedback frequency signals for outputting according to the sequence of the random number selecting signals. The multi-signal comparing phase frequency detector/converter simultaneously receives the N input reference frequency signals and the N feedback reference frequency signals outputted from the multiplexer. The multi-signal comparing phase frequency detector/converter compares each of the input reference frequency signals with a corresponding feedback reference frequency signal to obtain a comparison result, and outputs a comparison control signal according to the comparison result. The loop filter filters the comparison control signal and outputs a frequency control signal. The controllable oscillator receives the frequency control signal, and outputs an output frequency signal and adjusts the frequency of the output frequency signal according to the received frequency control signal. The frequency divider receives the output frequency signal and transforms the output frequency signal into the 2N feedback reference frequency signals.

Also consistent with the invention there is provided a method for synthesizing a frequency, the method comprising: N input reference frequency signals and N feedback reference frequency signals are received, in which frequencies of the input reference frequency signals are equivalent to one another while phases thereof are different from one another. Frequencies of the feedback reference frequency signals are equivalent to one another while phases thereof are different from one another. N is a positive integer greater than 1. The input reference frequency signals are correspondingly compared with the feedback reference frequency signals to obtain a comparison result, and a comparison control signal is outputted according to the comparison result. The comparison control signal is then filtered, and thus a frequency control signal is outputted. Next, the frequency of an output frequency signal is adjusted according to the frequency control signal, and then the output frequency signal is outputted. Finally, the output frequency signal is transformed into the feedback reference frequency signals.

### BRIEF DESCRIPTION OF THE DRAWINGS

The accompanying drawings are included to provide a further understanding of the invention and are incorporated in and constitute a part of this specification. The drawings illustrate embodiments of the invention and, together with the description, serve to explain the principles of the invention.

FIG. 1(a) is a functional block diagram illustrating a frequency synthesizer according to an exemplary embodiment consistent with the present invention.

FIG. 1(b) is a functional block diagram illustrating a multi-signal comparing phase frequency detector/converter according to an exemplary embodiment consistent with the present invention.

FIG. 1(c) is a functional block diagram illustrating a phase frequency detecting and converting apparatus according to an exemplary embodiment consistent with the present invention.

FIG. 2(a) is a functional block diagram illustrating a frequency synthesizer according to another exemplary embodiment consistent with the present invention.

FIG. 2(b) is a signal diagram illustrating the control of the frequency synthesizer of FIG. 2(a).

FIG. 3 is a functional block diagram illustrating a frequency synthesizer according to another exemplary embodiment consistent with the present invention.

FIG. 4 is a flow chart illustrating a method of synthesizing a frequency according to a frequency synthesizer provided by the exemplary embodiment consistent with the present invention.

FIG. 5 is a flow chart illustrating a method of synthesizing a frequency according to another frequency synthesizer provided by the exemplary embodiment consistent with the present invention.

FIG. 6(a) depicts a frequency spectrum analysis diagram of output frequency signals of a conventional frequency synthesizer.

FIG. 6(b) depicts a frequency spectrum analysis diagram of output frequency signals of a frequency synthesizer according to an exemplary embodiment consistent with the present invention.

FIG. 6(c) depicts a frequency spectrum analysis diagram of output frequency signals of a frequency synthesizer according to another exemplary embodiment consistent with the present invention.

### DESCRIPTION OF THE EMBODIMENTS

Reference will now be made in detail to the present embodiments of the invention, examples of which are illustrated in the accompanying drawings. Wherever possible, the same reference numbers are used in the drawings and the description to refer to the same or like parts.

According to an exemplary embodiment consistent with the present invention, a frequency synthesizer is provided for depressing a reference spur.

According to an exemplary embodiment consistent with the present invention, a frequency synthesizer is provided for outputting an output frequency signal which is stable and clean.

According to an exemplary embodiment consistent with the present invention, a method for synthesizing a frequency is provided for depressing a reference spur.

### First Embodiment

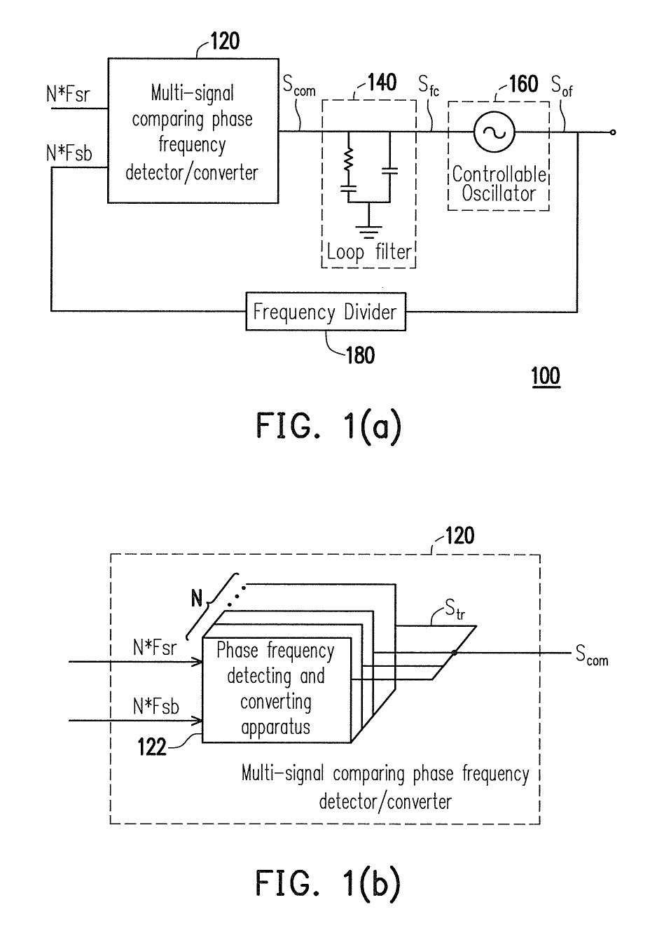

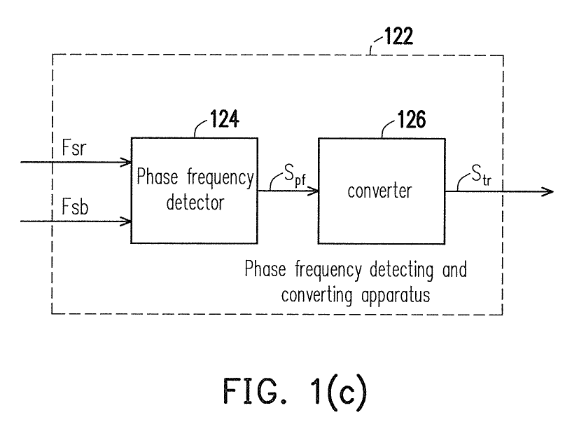

FIG. 1(a) is a functional block diagram illustrating a frequency synthesizer according to an exemplary embodiment consistent with the present invention. Referring to FIG. 1(a), it shows a frequency synthesizer 100 including a multi-signal comparing phase frequency detector/converter 120, a loop filter 140, a controllable oscillator 160, and a frequency divider 180. The multi-signal comparing phase frequency detector/converter 120 is coupled to the loop filter 140. The loop filter 140 is coupled to the controllable oscillator 160. The controllable oscillator 160 is coupled to the frequency divider 180. The frequency divider 180 is coupled to the multi-signal comparing phase frequency detector/converter 120. The multi-signal comparing phase frequency detector/converter 120 simultaneously receives N input reference frequency signals Fsr and N feedback reference frequency signals Fsb. Both of the N input reference frequency signals Fsr and the N feedback reference frequency signals Fsb have an equivalent frequency and different phases. In the present embodiment, the phase of each of the input reference frequency signals Fsr differs from one another by 360°/N, and the phase of each of the feedback reference frequency signals Fsb differs from one another by 360°/N. N is a positive integer greater than 1. However, it should be noted that the present invention should not be construed as being restricted as such. The phase differences can be arbitrarily set as long as the phase of the input reference frequency signal Fsr is equal to the phase of the corresponding feedback reference frequency signal Fsb. Further, the multi-signal comparing phase frequency detector/converter 120 compares each of the input reference frequency signals Fsr with the corresponding feedback reference frequency signal Fsb to obtain a comparison result, and outputs a comparison control signal S_{com} according to the comparison result. The loop filter 140 then filters the comparison control signal S_{com}, thus outputting a frequency control signal S_{fc}. The controllable oscillator 160 receives the frequency control signal S_{fc}, and outputs an output frequency signal S_{of} and adjusts the frequency of the output frequency signal S_{of} according to the received frequency control signal S_{fc}. The frequency divider 180 receives the output frequency signal S_{of} and transforms the output frequency signal S_{of} into the feedback reference frequency signals Fsb.

The multi-signal comparing phase frequency detector/converter 120 can be configured in many ways. For example, FIG. 1(b) is a functional block diagram illustrating a multi-signal comparing phase frequency detector/converter according to an embodiment of the present invention. Referring to FIG. 1(b), it shows a multi-signal comparing phase frequency detector/converter 120 including N phase frequency detecting and converting apparatuses 122. Each of the phase frequency detecting and converting apparatuses 122 is adapted for receiving one of the input reference frequency signals Fsr and a corresponding one of the feedback reference frequency signals Fsb, and comparing the received input reference frequency signal Fsr and the received corresponding feedback reference frequency signal Fsb, thus obtaining a comparison result. Therefore, according to comparison results of all of the phase frequency detecting and converting apparatuses 122, a comparison control signal S_{com} is outputted.

FIG. 1(c) is a functional block diagram illustrating a phase frequency detecting and converting apparatus 122 according to an embodiment of the present invention. Referring to FIG. 1(c), the phase frequency detecting and converting apparatus 122 includes a phase frequency detector 124 and a converter 126. The phase frequency detector 124 is coupled to the frequency divider 180. The phase frequency detector 124 receives one of the input reference frequency signals Fsr and a corresponding one of the feedback reference frequency signals Fsb, and compares the received input reference frequency signal Fsr with the corresponding feedback reference frequency signal Fsb, thus outputting a phase frequency difference signal S_{pf}. The converter 126 is coupled to the phase frequency detector 124 and the loop filter 140, for transforming and outputting a converted signal Sₜᵣ according to the phase frequency difference signal S_{pf}. All of the converted signals Sₜᵣ obtained thereby constitute the comparison control signal S_{com}.

Referring to FIGS. 1(a), 1(b), and 1(c) together, in the present embodiment, after receiving the N input reference frequency signals Fsr and the N feedback reference frequency signal Fsb, the N phase frequency detecting and converting apparatuses 122 of the multi-signal comparing phase frequency detector/converter 120 compare and convert the received N input reference frequency signals Fsr and the N feedback reference frequency signal Fsb. The comparison and conversion are electrical operations executed by all of the phase frequency detecting and converting apparatuses 122. As shown in FIG. 1(b), the phase frequency detecting and converting apparatuses 122 compare the input reference frequency signals Fsr and the feedback reference frequency signals Fsb which have equivalent frequencies and different phases. Details of the comparison result can be observed by referring to FIG. 1(c). As shown in FIG. 1(c), after comparing the input reference frequency signal Fsr with the feedback reference frequency signal Fsb, the phase frequency detector 124 outputs the phase frequency difference signal S_{pf} to the converter 126. In the current embodiment, the phase frequency difference signal S_{pf} is, for example, a voltage signal, and therefore the converter 126 converts the phase frequency difference signal S_{pf} into a current signal. During the same period, a plurality of converted signals Sₜᵣ are outputted, and all of the converted signals Sₜᵣ are combined into the comparison control signal S_{com}. However, it should be noted that the present invention is not restricted to be as such. In other words, the phase frequency difference signal S_{pf} is not restricted to be a voltage signal. Rather, it can also be a digital code. The converted signals Sₜᵣ are not restricted to be current signals, either. They can also be digital control signals. In this case, the comparison control signal S_{com} is a combination signal of the converted signals Sₜᵣ in digital control signal forms.

Referring to FIG. 1(a) again, after receiving the comparison control signal S_{com}, the loop filter 140 filters the received comparison control signal S_{com}. In the current embodiment, the loop filter 140 is preferred to be, but is not restricted to be, a low pass filter. Such a low pass filter is adapted for removing the high frequency ingredient of the comparison control signal S_{com} and remaining the low frequency ingredient, thus outputting the frequency control signal S_{fc}. In such a way, the low pass filter prevents high frequency noises from immediately affecting the output frequency variation of the frequency synthesizer 100. However, the loop filter 140 can also be other kinds of filters, e.g., a band pass filter. The frequency control signal S_{fc} controls an output frequency signal S_{of} outputted from the controllable oscillator 160. In the present embodiment, the controllable oscillator 160 is preferred, but not restricted, to be a voltage control oscillator (VCO). Certainly, other oscillators (e.g., a digital control oscillator) can also be selected if the output frequency signals can be controlled by the frequency control signal S_{fc}. The output frequency signal S_{of} is then transmitted to the frequency divider 180 for dividing frequencies. It should be noted that the frequency divider 180 divides the frequency of the output frequency signal S_{of} and transforms the output frequency signal S_{of} into a plurality of feedback reference frequency signals Fsb having equivalent frequencies and different phases. Output signals of various elements in the frequency synthesizer 100 will vary until the frequency synthesizer 100 is in a locked state. In this case, the frequency synthesizer 100 obtains a stable and clean output frequency signal S_{of}.

It can be learned from the foregoing that the exemplary embodiments consistent with the present invention compares multiple groups of the input reference frequency signals Fsr and the corresponding feedback reference frequency signals Fsb having equivalent frequencies and different phases during a period of the reference frequency. As such, in a single period, the loop filter 140 is charged/discharged or performed with digital code adding/subtracting operations for many times. Therefore, the amplitude of the loop filter 140 that is charged/discharged or performed with digital code adding/subtracting operations is relatively small. Hence, the output frequency control signal S_{fc} inputted into the controllable oscillator 160 in a single period can have various values with relative small amplitude. In comparison, the conventional technology can achieve only one variation with a greater amplitude in a single period for controlling the VCO. As such, the multi-signal comparing phase frequency detector/converter 120 of the exemplary embodiment consistent with the present invention is adapted for depressing a reference spur and obtaining a clean and stable output frequency signal S_{of}.

### Second Embodiment

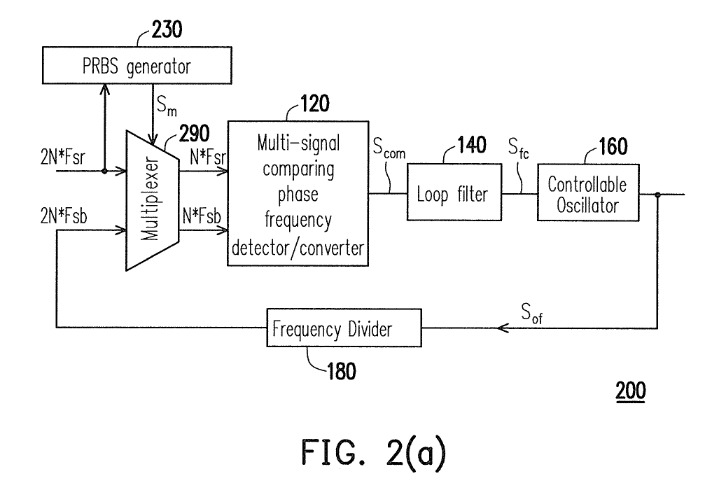

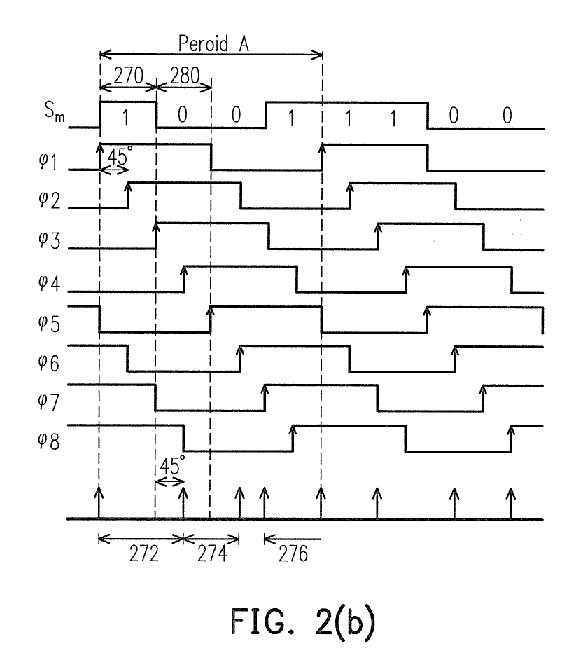

FIG. 2(a) is a functional block diagram illustrating a frequency synthesizer according to another embodiment of the present invention. Referring to FIGS. 1(a) and 2(a) together, a frequency synthesizer 200 includes a pseudo-random binary sequence (PRBS) generator 230, a multiplexer 290, a multi-signal comparing phase frequency detector/converter 120, a loop filter 140, a controllable oscillator 160, and a frequency divider 180. The PRBS generator 230 is adapted for generating random number selecting signals Sₘ.

The multiplexer 290 receives 2N input reference frequency signals Fsr, 2N feedback reference frequency signals Fsb, and the random number selecting signals Sₘ, in which N is a positive integer greater than 1. The 2N input reference frequency signals Fsr and the 2N feedback reference frequency signals Fsb have equivalent frequencies and different phases. The multiplexer 290 is adapted to sequentially select N from the 2N input reference frequency signals Fsr for outputting according to a sequence of the random number selecting signals Sₘ, and sequentially select N from the 2N feedback frequency signals Fsb for outputting according to the sequence of the random number selecting signals Sₘ. In the current embodiment, the phase of each of the input reference frequency signals Fsr differs from one another by 360°/2N, and the phase of each of the feedback reference frequency signals Fsb differs from one another by 360°/2N. However, it should be noted that the present invention should not be construed as being restricted as such. The phase differences can be arbitrarily set as long as the phase of the input reference frequency signal Fsr is equal to the phase of the corresponding feedback reference frequency signal Fsb.

In the current embodiment, when the random number selecting signal Sₘ outputted by the PRBS generator 230 to the multiplexer 290 is 1, the multiplexer 290 selects an odd number group of the input reference frequency signals Fsr and the feedback reference frequency signals Fsb and outputs the same into the multi-signal comparing phase frequency detector/converter 120. When the random number selecting signal Sₘ outputted by the PRBS generator 230 to the multiplexer 290 is 0, the multiplexer 290 selects an even number group of the input reference frequency signals Fsr and the feedback reference frequency signals Fsb and outputs the same into the multi-signal comparing phase frequency detector/converter 120. However, this is not exemplified for restricting the scope of the present invention. For example, the multiplexer 290 can also select the odd group when the random number selecting signal Sₘ is 0.

In the current embodiment, phases of the odd number group of the input reference frequency signals Fsr and the feedback reference frequency signals Fsb are 360°/2N, 360°/2N+360°/N, 360°/2N+360°/N*2, . . . , 360°/2N+360°/N*(N−1), respectively, while phases of the even number group of the input reference frequency signals Fsr and the feedback reference frequency signals Fsb are 360°/N, 360°/N*2, . . . , 360°/N*(N−1), 360°, respectively. However, this is not exemplified for restricting the scope of the present invention. For example, the phases of the even number group of the input reference frequency signals Fsr and the feedback reference frequency signals Fsb can also be set as 360°/N−θ, 360°/N*2−θ, . . . , 360°/N*(N−1)−θ, 360°−θ, respectively, in which θ is a predetermined phase angle.

In the current embodiment, in addition to the PRBS generator 230 and the multiplexer 290, other functional blocks, such as the multi-signal comparing phase frequency detector/converter 120, the loop filter 140, the controllable oscillator 160, and the frequency divider 180, are similar to those described in the first embodiment and can be learned by referring to the discussions hereinbefore. Hence, no further descriptions are provided.

FIG. 2(b) is a signal diagram illustrating the control of the frequency synthesizer of FIG. 2(a). Referring to FIGS. 2(a) and 2(b), in the current embodiment, it is assumed that N=4. As shown in FIG. 2(b), the random number selecting signals Sₘ are 1, 0, 0, 1, 1, 1, 0, 0, in sequence. In one period, the random number selecting signals Sₘ present same amount of 1s and 0s. For example, in a period A, there are two 1s and two 0s that are randomly presented. In FIG. 2(b), totally eight signals are shown, i.e., φ1, φ2, φ3, φ4, φ5, φ6, φ7, and φ8. Each of the eight signals shown in FIG. 2(b) can be considered as an input reference frequency signal Fsr of FIG. 2(a), and each of the phases of the eight signals differs from one another by 45°. The signals φ1, φ3, φ5, and φ7 are allocated to be the input reference frequency signals Fsr of the odd number group, while the signals φ2, φ4, φ6, and φ8 are allocated to be the input reference frequency signals Fsr of the even number group. In the current embodiment, the phases of the odd number group of the input reference frequency signals Fsr and the feedback reference frequency signals Fsb are 360°/2N, 360°/2N+360°/N, 360°/2N+360°/N*2, . . . , 360°/2N+360°/N*(N−1), respectively, while the phases of the even number group of the input reference frequency signals Fsr and the feedback reference frequency signals Fsb are 360°/N, 360°/N*2, . . . , 360°/N*(N−1), 360°, respectively, in which N=4. As such, the phases of the odd number group of the input reference frequency signals Fsr and the feedback reference frequency signals Fsb (i.e., φ1, φ3, φ5, and φ7) are 45°, 135°, 225°, and 315°, respectively, and the phases of the even number group of the input reference frequency signals Fsr (i.e., φ2, φ4,φ6, and φ8) are 90°, 180°, 270°, and 360°, respectively. As shown in an interval 270 of FIG. 2(b), one of the input reference frequency signals Fsr φ1 and φ2 is selected for being compared with a feedback reference frequency signal Fsb corresponding thereto. In this interval 270, the random number selecting signal Sₘ is 1, and therefore φ1 of the odd number group is selected for being compared. Alternatively, as shown in an interval 280 of FIG. 2(b), one of the input reference frequency signals Fsr φ3 and φ4 is selected for being compared with a feedback reference frequency signal Fsb corresponding thereto. In this interval 280, the random number selecting signal Sₘ is 0, and therefore φ4 of the even number group is selected for being compared. As such, the current embodiment employs the PRBS generator 230 for randomizing the time points of comparing the input reference frequency signals Fsr with the feedback reference frequency signals Fsb, as shown in intervals 272, 274, and 276 of FIG. 2(b). In such a way, the present invention is adapted for further depressing the reference spur.

Moreover, the multi-signal comparing phase frequency detector/converter 120 can be realized as that of the first embodiment as shown in FIGS. 1(b) and 1(c) and therefore is not further iterated hereby.

### Third Embodiment

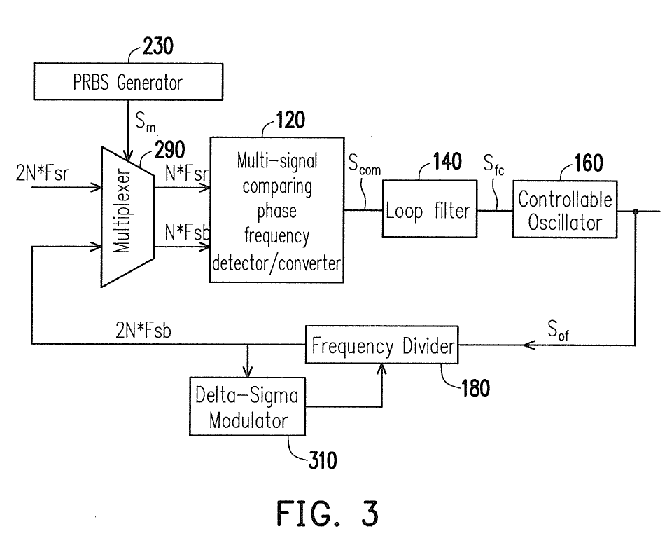

FIG. 3 is a functional block diagram illustrating a frequency synthesizer according to another embodiment of the present invention. Referring to FIGS. 3 and 2(a), the difference between the third embodiment and the second embodiment lies in that the third embodiment further employs a delta-sigma modulator 310 coupled to the frequency divider 180. In the third embodiment, the delta-sigma modulator 310 is adapted for extending the application of the present invention from an integral frequency synthesizer to a fractional frequency synthesizer, while the other elements described in the current embodiment remain the same as shown in the second embodiment and are not further iterated hereby.

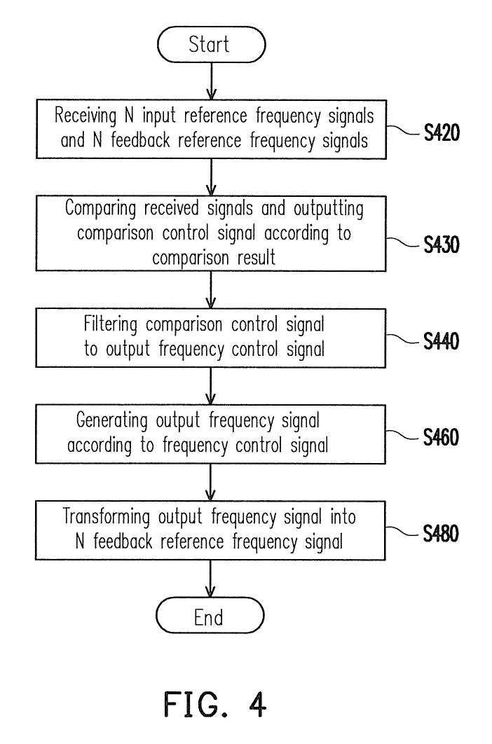

FIG. 4 is a flow chart illustrating a method of synthesizing a frequency according to a frequency synthesizer provided by the present invention. Referring to FIG. 4, first, in step S420, N input reference frequency signals and N feedback reference frequency signals are received, in which N is a positive integer greater than 1. The N input reference frequency signals and the N feedback reference frequency signals have an equivalent frequency and different phases. Next, in step S430, the input reference frequency signals are compared with corresponding feedback reference frequency signals to obtain comparison results, and a comparison control signal is outputted according to the comparison results. After that, in step S440, the comparison control signal is filtered, and thus a frequency control signal is outputted. In step S460, a frequency of an output frequency signal is adjusted according to the frequency control signal, and then the output frequency signal is outputted. Finally, in step S480, the output frequency signal is transformed into the N feedback reference frequency signals.

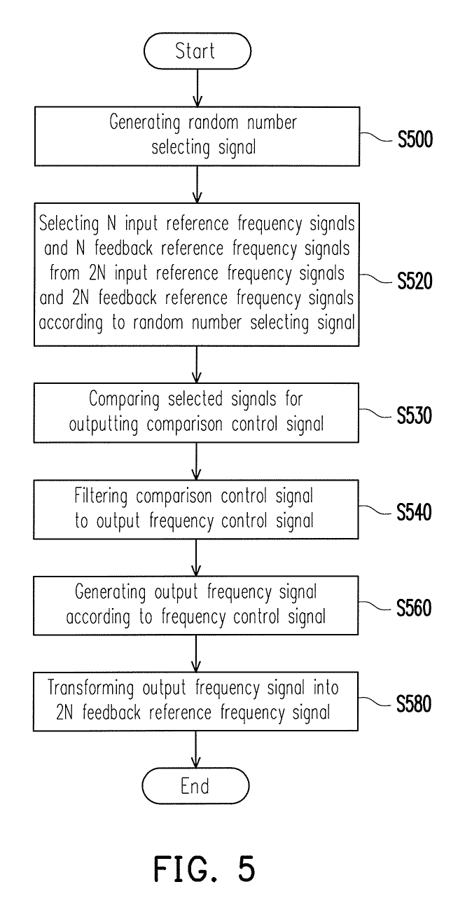

FIG. 5 is a flow chart illustrating a method of synthesizing a frequency according to another frequency synthesizer provided by the present invention. Referring to FIG. 5, first, in step S500, a random number selecting signal is generated. In the current embodiment, the numbers of the random number selecting signals respectively presenting 1 and 0 are the same within a predetermined period. As such, the present embodiment can effectively extent and depress the influence of the reference spur posed on the main frequency. However, the present embodiment is not provided for restricting the scope of the present invention. Next, in step S520, 2N input reference frequency signals, 2N feedback reference frequency signals, and the random number selecting signals are received, in which N is a positive integer greater than 1. The 2N input reference frequency signals and the 2N feedback reference frequency signals have an equivalent frequency and different phases. N input reference frequency signals are selected from the 2N input reference frequency signals for outputting according to a sequence of the random number selecting signals. N feedback reference frequency signals are selected from the 2N feedback reference frequency signals for outputting according to the sequence of the random number selecting signals. Thereafter, in step S530, the selected input reference frequency signals are compared with corresponding selected feedback reference frequency signals to obtain comparison results thereof, and an output control signal is outputted according to the comparison results. After that, in step S540, the comparison control signal is filtered, and thus a frequency control signal is outputted. In step S560, a frequency of an output frequency signal is adjusted according to the frequency control signal, and then the output frequency signal is outputted. Finally, in step S580, the output frequency signal is transformed into the 2N feedback reference frequency signals.

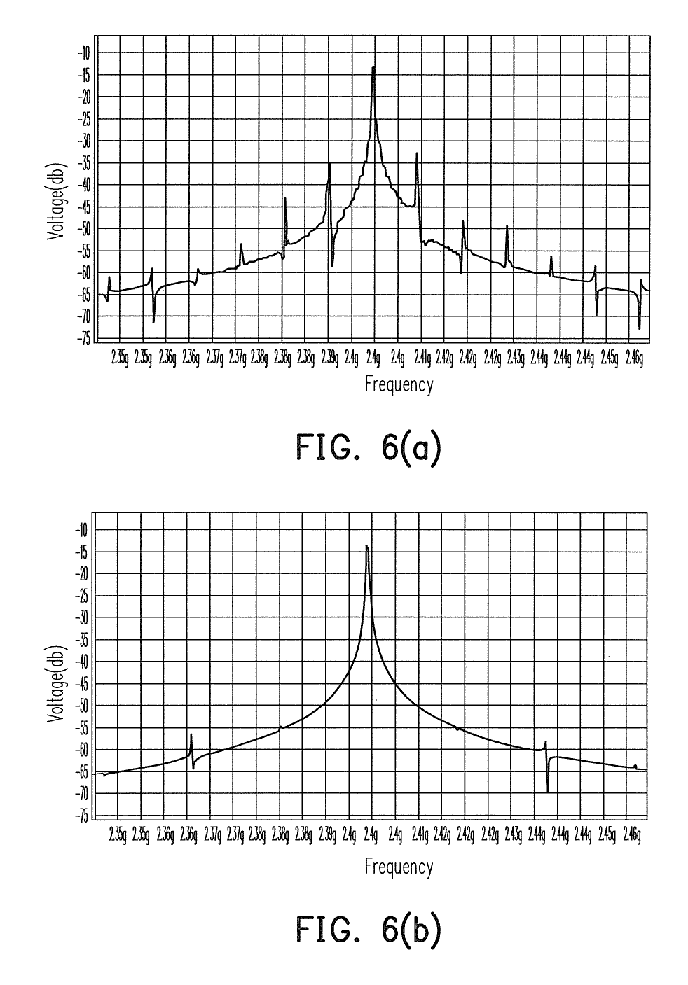

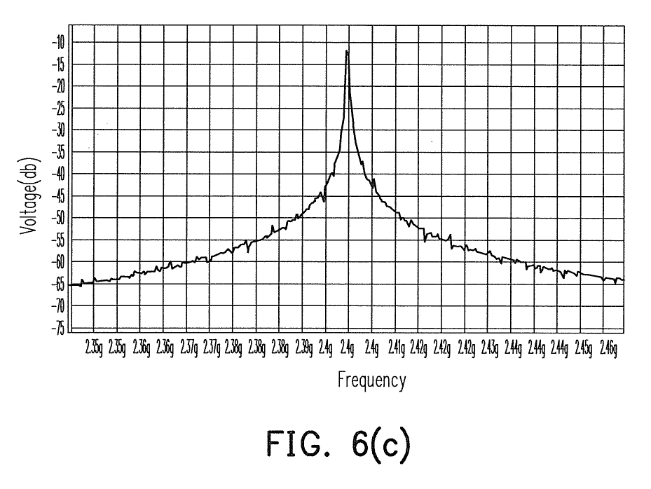

FIGS. 6(a), 6(b), and 6(c) are experimental data for illustrating the present invention. FIG. 6(a) depicts a frequency spectrum analysis diagram of output frequency signals of a conventional frequency synthesizer, which employs an individual phase frequency detector and an individual converter. FIG. 6(b) depicts a frequency spectrum analysis diagram of output frequency signals of a frequency synthesizer according to an embodiment of the present invention, which employs a multi-signal comparing phase frequency detector/converter including four phase frequency detecting and converting apparatuses. As such, comparing FIG. 6(a) with FIG. 6(b), it can be learned that the amount of the reference spurs of FIG. 6(b) are apparently less than those of FIG. 6(a), and the amplitudes of the reference spurs of FIG. 6(b) are apparently lower than those of FIG. 6(a). FIG. 6(c) depicts a frequency spectrum analysis diagram of output frequency signals of a frequency synthesizer according to another embodiment of the present invention, which further employs a PRBS generator and a multiplexer in addition to the four phase frequency detecting and converting apparatuses. Accordingly, it can be seen that the reference spurs of FIG. 6(c) almost do not exist, and the amount and the amplitudes of the reference spurs of FIG. 6(c) are the least and the lowest among the three drawings.

In summary, the embodiments consistent with the present invention provides a frequency synthesizer employing a multi-signal comparing phase frequency detector/converter. The multi-signal comparing phase frequency detector/converter includes a plurality of phase frequency detecting and converting apparatuses simultaneously operated for depressing a reference spur. In this manner, the embodiments consistent with the present invention can be considered as a frequency synthesizer having a function of a digital low pass filter. With proper designs, the present invention can be adapted for moving the reference spurs out from the application frequency range, thus lowering the reference spurs to an acceptable value.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A frequency synthesizer, comprising:
a multi-signal comparing phase frequency detector/converter, for simultaneously receiving N input reference frequency signals and N feedback reference frequency signals, wherein frequencies of the input reference frequency signals are equivalent to one another while phases of the input reference frequency signals are different from one another, and frequencies of the feedback reference frequency signals are equivalent to one another while phases of the feedback reference frequency signals are different from one another, and N is a positive integer greater than 1, wherein the multi-signal comparing phase frequency detector/converter compares each of the input reference frequency signals with the corresponding feedback reference frequency signal to obtain a comparison result, and outputs a comparison control signal according to the comparison result;
a loop filter, coupled to the multi-signal comparing phase frequency detector/converter, for filtering the comparison control signal and outputting a frequency control signal;
a controllable oscillator, coupled to the loop filter, for receiving the frequency control signal, and adjusting a frequency of an output frequency signal according to the received frequency control signal; and
a frequency divider, coupled to the controllable oscillator and the multi-signal comparing phase frequency detector/converter, for transforming the output frequency signal into the feedback reference frequency signals.

2. The frequency synthesizer according to claim 1, wherein the multi-signal comparing phase frequency detector/converter comprises:
N phase frequency detecting and converting apparatuses, each of the phase frequency detecting and converting apparatuses receiving and comparing one of the input reference frequency signals with one of the feedback reference frequency signals corresponding to the received one of the input reference frequency signals to obtain a comparison result, wherein the multi-signal comparing phase frequency detector/converter outputs the comparison control signal according to the comparison results of all of the phase frequency detecting and converting apparatuses.

3. The frequency synthesizer according to claim 2, wherein each of the phase frequency detecting and converting apparatuses comprises:
a phase frequency detector, coupled to the frequency divider for receiving one of the input reference frequency signals and one of the feedback reference frequency signals corresponding to the received input reference frequency signal, and comparing the received input reference frequency signal with the corresponding feedback reference frequency signal and outputting a phase frequency difference signal; and
a converter, coupled to the phase frequency detector and the loop filter, for converting and outputting a converted signal according to the phase frequency difference signal, wherein the converted signals outputted from all of the phase frequency detecting and converting apparatuses constitute the comparison control signal.

4. The frequency synthesizer according to claim 3, wherein the phase frequency difference signal is a voltage signal or a digital code.

5. The frequency synthesizer according to claim 3, wherein the converted signal is a current signal or a digital control signal.

6. The frequency synthesizer according to claim 1, wherein the phases of the input reference frequency signals differ from one another by 360°/N, and the phases of the feedback reference frequency signals differ from one another by 360°/N.

7. The frequency synthesizer according to claim 1, wherein the controllable oscillator is a voltage control oscillator (VCO) or a digital control oscillator.

8. The frequency synthesizer according to claim 1, wherein the loop filter is a low pass filter.

9. A frequency synthesizer, comprising:
a pseudo-random binary sequence (PRBS) generator, adapted for generating a random number selecting signal;
a multiplexer, coupled to the PRBS generator, for receiving 2N input reference frequency signals, 2N feedback reference frequency signals, and the random number selecting signal, wherein frequencies of the input reference frequency signals are equivalent to one another, while phases of the input reference frequency signals are different from one another, and frequencies of the feedback reference frequency signals are equivalent to one another, while phases of the feedback reference frequency signals are different from one another, and N is a positive integer greater than 1, wherein the multiplexer selects N input reference frequency signals from the 2N input reference frequency signals for outputting according to the random number selecting signal, and selects N feedback frequency signals from the 2N feedback frequency signals for outputting according to the random number selecting signal;
a multi-signal comparing phase frequency detector/converter, coupled to the multiplexer for receiving the N input reference frequency signals and the N feedback reference frequency signals outputted from the multiplexer, wherein the multi-signal comparing phase frequency detector/converter compares each of the received input reference frequency signals with a corresponding feedback reference frequency signal to obtain a comparison result, and outputs a comparison control signal according to the comparison result;
a loop filter, coupled to the multi-signal comparing phase frequency detector/converter, for filtering the comparison control signal and outputting a frequency control signal;
a controllable oscillator, coupled to the loop filter for receiving the frequency control signal, and adjusting a frequency of an output frequency signal according to the received frequency control signal; and
a frequency divider, coupled to the controllable oscillator and the multiplexer, for transforming the output frequency signal into the feedback reference frequency signals.

10. The frequency synthesizer according to claim 9, wherein the multi-signal comparing phase frequency detector/converter comprises:
N phase frequency detecting and converting apparatuses, each of the phase frequency detecting and converting apparatuses receiving and comparing one of the input reference frequency signals with one of the feedback reference frequency signals corresponding to the received one of the input reference frequency signals to obtain a comparison result, wherein the multi-signal comparing phase frequency detector/converter outputs the comparison control signal according to the comparison results of all of the phase frequency detecting and converting apparatuses.

11. The frequency synthesizer according to claim 10, wherein each of the phase frequency detecting and converting apparatuses comprises:
a phase frequency detector, coupled to the multiplexer for receiving one of the input reference frequency signals and one of the feedback reference frequency signals corresponding to the received input reference frequency signal, and comparing the received input reference frequency signal with the corresponding feedback reference frequency signal and outputting a phase frequency difference signal; and
a converter, coupled to the phase frequency detector and the loop filter, for converting and outputting a converted signal according to the phase frequency difference signal, wherein the converted signals outputted from all of the phase frequency detecting and converting apparatuses constitute the comparison control signal.

12. The frequency synthesizer according to claim 11, wherein the phase frequency difference signal is a voltage signal or a digital code.

13. The frequency synthesizer according to claim 11, wherein the converted signal is a current signal or a digital control signal.

14. The frequency synthesizer according to claim 9, wherein the phases of the input reference frequency signals differ from one another by 360°/2N, and the phases of the feedback reference frequency signals differ from one another by 360°/2N.

15. The frequency synthesizer according to claim 14, wherein when the random number selecting signal is 1, an odd number group of the input reference frequency signals and the feedback reference frequency signals is selected, and when the random number selecting signal is 0, an even number group of the input reference frequency signals and the feedback reference frequency signals is selected, wherein phases of the input reference frequency signals of the odd number group are 360°/2N, 360°/2N+360°/N, 360°/2N+360°/N*2, . . . , 360°/2N+360°/N*(N−1), respectively, and phases of the input reference frequency signals and the feedback reference frequency signals of the even number group are 360°/N, 360°/N*2, . . . , 360°/N*(N−1), 360°, respectively.

16. The frequency synthesizer according to claim 9, further comprising a delta-sigma modulator coupled to the frequency divider, wherein when facilitated with the delta-sigma modulator and the frequency divider, the frequency synthesizer constitutes a fractional frequency synthesizer.

17. The frequency synthesizer according to claim 9, wherein the controllable oscillator is a voltage control oscillator (VCO) or a digital control oscillator.

18. The frequency synthesizer according to claim 9, wherein the loop filter is a low pass filter.

19. A method for synthesizing a frequency, comprising:
receiving N input reference frequency signals and N feedback reference frequency signals, wherein frequencies of the input reference frequency signals are equivalent to one another while phases of the input reference frequency signals are different from one another, frequencies of the feedback reference frequency signals are equivalent to one another while phases of the feedback reference frequency signals are different from one another, and N is a positive integer greater than 1;
comparing the input reference frequency signals with the corresponding feedback reference frequency signals to obtain a comparison result, and outputting a comparison control signal according to the comparison result;
filtering the comparison control signal and outputting a frequency control signal;
adjusting a frequency of an output frequency signal according to the frequency control signal and outputting the output frequency signal; and
transforming the output frequency signal to the feedback reference frequency signals.

20. The method according to claim 19, wherein before the step of receiving the N input reference frequency signals and the N feedback reference frequency signals, the method further comprises:
generating a random number selecting signal; and
receiving 2N input reference frequency signals, 2N feedback reference frequency signals, and the random number selecting signal, wherein frequencies of all of the input reference frequency signals are equivalent to one another while phases of all of the input reference frequency signals are different from one another, and frequencies of all of the feedback reference frequency signals are equivalent to one another while phases of all of the feedback reference frequency signals are different from one another, selecting the N input reference frequency signals from the 2N input reference frequency signals for outputting according to the random number selecting signal, and selecting the N feedback frequency signals from the 2N feedback frequency signals for outputting according to the random number selecting signal for subsequent operations.
